(19) United States
(12) Patent Application Publication
(10) Pub. No.: US 2023/0223428 A1
(43) Pub. Date: Jul. 13, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: Yinghao PENG, Hefei City (CN)

(21) Appl. No.: 17/658,303

(22) Filed: Apr. 7, 2022

(30) Foreign Application Priority Data
Jan. 13, 2022 (CN) 202210036539.7

(51) Int. Cl. H01L 49/02

(52) U.S. Cl. CPC H01L 28/87; H01L 28/91; H01L 27/108

(57) ABSTRACT

The present disclosure relates to a semiconductor structure and a manufacturing method thereof. The manufacturing method of a semiconductor structure includes: providing a substrate, where a plurality of first electrodes arranged at intervals are formed on the substrate; forming a dielectric layer on surfaces of the first electrodes, where a duration of a single purge required for forming the dielectric layer is greater than or equal to a first threshold; or forming a multi-dielectric-layers stack on the surfaces of the first electrodes, where a duration of a single purge required for forming a first dielectric layer of the multi-dielectric-layers stack is greater than or equal to the first threshold. The manufacturing method can improve the manufacturing process of the capacitor in the semiconductor structure, to avoid defects such as current leakages and relatively small capacitance values, thereby ensuring the electrical performance of the semiconductor structure.

### CROSS-REFERENCE TO RELATED APPLICATIONS

This application claims the priority of Chinese Patent Application No. 202210036539.7, submitted to the Chinese Intellectual Property Office on Jan. 13, 2022, the disclosure of which is incorporated herein in its entirety by reference.

### TECHNICAL FIELD

The present disclosure relates to the field of semiconductor integrated circuit manufacturing technologies, in particular to a semiconductor structure and a manufacturing method thereof.

### BACKGROUND

As a commonly used semiconductor memory in electronic devices such as computers, a dynamic random access memory (DRAM) usually includes a plurality of memory cells. Each memory cell includes: a capacitor and a transistor electrically connected to the capacitor. The capacitor is typically formed by a first electrode, a second electrode, and a dielectric layer between the first electrode and the second electrode.

With the development of DRAM-related technologies, high speed, high integration density and low power consumption have become the mainstream requirements for the DRAM. However, after the structural size of the DRAM has been continuously reduced, especially in a DRAM with a critical dimension less than 20 nm, the thickness of the dielectric layer is likely to cause the quantum tunneling effect, resulting in defects such as current leakages.

### SUMMARY

Some embodiments of the present disclosure provide a manufacturing method of a semiconductor structure, including the following steps:

providing a substrate, where a plurality of first electrodes arranged at intervals are formed on the substrate;

forming a dielectric layer on surfaces of the first electrodes, where a duration of a single purge required for forming the dielectric layer is greater than or equal to a first threshold; or

forming a multi-dielectric-layers stack on the surfaces of the first electrodes, where a duration of a single purge required for forming a first dielectric layer of the multi-dielectric-layers stack is greater than or equal to the first threshold.

In some embodiments, steps of forming the dielectric layer are as follows:

depositing a dielectric layer precursor;

purging a structure obtained after the dielectric layer precursor is deposited;

oxidizing the dielectric layer precursor and converting the dielectric layer precursor into the dielectric layer; and

purging a structure obtained after the dielectric layer is formed.

In some embodiments, the dielectric layer precursor is deposited at a temperature less than or equal to a second threshold.

In some embodiments, the second threshold includes 260° C.

In some embodiments, the dielectric layer precursor is deposited at a temperature ranging from 230° C. to 250° C.

In some embodiments, a purge gas used in the process of forming the dielectric layer includes nitrogen or argon.

In some embodiments, in the process of forming the dielectric layer, a flow rate of the purge gas ranges from 800 sccm to 1600 sccm; and a pressure of the purge gas ranges from 0.2 torr to 2 torr.

In some embodiments, in the process of forming the dielectric layer, a temperature of the purge gas ranges from 200° C. to 350° C.

In some embodiments, the first threshold includes 90 s and 100 s. In some embodiments, during the forming a dielectric layer on surfaces of the first electrodes, the duration of a single purge required for forming the dielectric layer ranges from 90 s to 120 s.

In some embodiments, during the forming a multi-dielectric-layers stack on the surfaces of the first electrodes, the duration of the single purge required for forming the first dielectric layer of the multi-dielectric-layers stack ranges from 90 s to 120 s.

In some embodiments, during the forming a multi-dielectric-layers stack on the surfaces of the first electrodes, a duration of a single purge required for forming another dielectric layer of the multi-dielectric-layers stack other than the first dielectric layer of the multi-dielectric-layers stack is less than that of the single purge required for forming the first dielectric layer of the multi-dielectric-layers stack.

In some embodiments, the forming a multi-dielectric-layers stack on the surfaces of the first electrodes includes: forming a plurality of zirconium oxide (ZrO₂) dielectric layers and aluminum oxide (Al₂O₃) dielectric layers, the ZrO₂ dielectric layers and the Al₂O₃ dielectric layers are alternately arranged in a stacked manner on the surfaces of the first electrodes, where the first dielectric layer of the multi-dielectric-layers stack is one of the ZrO₂ dielectric layers. In some embodiments, a dielectric layer precursor of each of the ZrO₂ dielectric layers includes a metal zirconium source. A dielectric layer precursor of each of the Al₂O₃ dielectric layers includes a metal aluminum source.

In some embodiments, during the forming a multi-dielectric-layers stack on the surfaces of the first electrodes, two adjacent dielectric layers are made of different materials, and two adjacent dielectric layers include at least one wide-bandgap dielectric layer.

In some embodiments, the wide-bandgap dielectric layer includes an Al₂O₃ dielectric layer.

In some embodiments, the manufacturing method further includes: forming a plurality of second electrodes on a surface of the dielectric layer. One of the first electrodes, one of the second electrodes, and the dielectric layer located between the first electrode and the second electrode form a capacitor.

Some embodiments of the present disclosure further provide a semiconductor structure, which is manufactured by using the manufacturing method in some of the foregoing embodiments. A semiconductor structure includes: a substrate and a plurality of capacitors formed on the substrate. Each of the capacitors includes a first electrode, a second electrode and at least one dielectric layer located between the first electrode and the second electrode; and the capacitors are formed by using the manufacturing method according to some of the foregoing embodiments.

In some embodiments, the first electrode includes a columnar electrode, and a second electrode accommodating hole is provided between adjacent first electrodes. The second electrode is located in the second electrode accommodating hole.

In some embodiments, the at least one dielectric layer includes a plurality of ZrO₂ dielectric layers and Al₂O₃ dielectric layers, the ZrO₂ dielectric layers and the Al₂O₃ dielectric layers are alternately arranged in a stacked manner, where a first dielectric layer close to the first electrode is the ZrO₂ dielectric layer.

In some embodiments, a thickness of the first dielectric layer close to the first electrode ranges from 3.5 nm to 5.5 nm.

In the embodiments of the present disclosure, the duration of the single purge required in the process of forming the dielectric layer or the duration of the single purge required for forming the first dielectric layer in the multi-dielectric-layers stack is limited. For example, the duration of the foregoing single purge is greater than or equal to the first threshold. In this way, a single purge with a longer duration can reduce or eliminate the residual water vapor that may occur during the formation of the dielectric layer, and improve the stability of the dielectric layer formation process, to ensure that a uniform dielectric layer is formed on the first electrodes, thereby improving the electrical performance of the capacitor, and avoiding current leakages and relatively small capacitance values due to the relatively small thickness of the partial dielectric layer.

In addition, in the embodiment of the present disclosure, by controlling the deposition temperature of the dielectric layer precursor to be less than the second threshold, a lower deposition temperature can be used for improving lattice structure of the dielectric layer precursor to effectively increase the dielectric constant (k) of the dielectric layer. Therefore, under the same size condition, the amount of charge stored by the capacitor can be increased, to increase the capacitance value of the capacitor where the dielectric layer is located, thereby avoiding improving reading and writing efficiency and increasing energy consumption.

In addition, in the embodiments of the present disclosure, two kinds of high-k materials with different dielectric constants and different band gaps are used to form a plurality of dielectric layers in the capacitors through discrete arrangement, which can ensure that the capacitors have optimal electrical performance.

### BRIEF DESCRIPTION OF THE DRAWINGS

To describe the technical solutions in the embodiments of the present application or in the conventional art more clearly, the following briefly describes the accompanying drawings required for describing the embodiments or the conventional art. Apparently, the accompanying drawings in the following description show merely some embodiments of the present application, and a person of ordinary skill in the art may still derive other accompanying drawings from these accompanying drawings without creative efforts.

FIG. 1 is a flowchart of a manufacturing method of a semiconductor structure according to an embodiment;

FIG. 2 is a flowchart of another manufacturing method of a semiconductor structure according to an embodiment;

FIG. 3 is a flowchart of a manufacturing method of a dielectric layer according to an embodiment;

FIG. 4 is a flowchart of another manufacturing method of a semiconductor structure according to an embodiment;

FIG. 5 is a schematic structural diagram of a semiconductor structure according to an embodiment;

FIG. 6 is a schematic structural diagram of a dielectric layer in a capacitor according to an embodiment;

FIG. 7 is a schematic diagram of a correspondence between a dielectric constant (k) and a band gap that are of a material according to an embodiment;

FIG. 8 is a schematic diagram of a structure obtained after a dielectric-layer set is formed according to an embodiment;

FIG. 9 is a schematic diagram of a structure obtained after a hard mask is formed according to an embodiment;

FIG. 10 is a schematic diagram of a structure obtained after first electrode accommodating holes are formed according to an embodiment;

FIG. 11 is a schematic diagram of a structure obtained after a first electrode material layer is formed according to an embodiment;

FIG. 12 is a schematic diagram of a structure obtained after first electrodes are formed according to an embodiment;

FIG. 13 is a schematic diagram of a structure obtained after basic second electrode accommodating holes are formed according to an embodiment;

FIG. 14 is a schematic diagram of a structure obtained after second electrode accommodating holes are formed according to an embodiment;

FIG. 15 is a schematic diagram of a structure obtained after a dielectric layer is formed according to an embodiment;

FIG. 16 is a time sequence diagram of a formation cycle of the dielectric layer shown in FIG. 15; and

FIG. 17 is a schematic diagram of a structure obtained after second electrodes are formed according to an embodiment.

### REFERENCE NUMERALS

1-Substrate, and 11-Memory node contact structure; 2-Capacitor, 21-First electrode, 22-Second electrode, 23-Dielectric layer; 231-ZrO₂ dielectric layer, 232-Al₂O₃ dielectric layer; 3-Dielectric-layer set, 31-First silicon nitride layer, 32-Silicon oxide layer, 33-Second silicon nitride layer; 4-Hard mask; 210-First electrode material layer; H1-First electrode accommodating hole, H21-Basic second electrode accommodating hole, H2-Second electrode accommodating hole; T1-Thickness of a first ZrO₂ dielectric layer, T2-Thickness of the Al₂O₃ dielectric layer, and T3-Thicknesses of the other ZrO₂ dielectric layers.

### DETAILED DESCRIPTION

To facilitate the understanding of the present application, the present application is described more completely below with reference to the accompanying drawings. The embodiments of the present application are shown in the accompanying drawings. However, the present application may be embodied in various forms without being limited to the embodiments described herein. These embodiments are provided in order to make the present application more thorough and comprehensive.

Unless otherwise defined, all technical and scientific terms used herein have the same meaning as commonly understood by those skilled in the technical field of the present application. The terms mentioned herein are merely for the purpose of describing specific embodiments, rather than to limit the present application.

It should be understood that when an element or layer is described as “on”, “adjacent to”, “connected to” or “coupled to” another element or layer, it can be on, adjacent to, connected to, or coupled to the another element or layer directly, or intervening elements or layers may be present. On the contrary, when an element is described as “directly on”, “directly adjacent to”, “directly connected to” or “directly coupled to” another element or layer, there are no intervening elements or layers.

It should be understood that although terms such as first and second may be used to describe various elements, components, regions, layers, doped types and/or sections, these elements, components, regions, layers, doped types and/or sections should not be limited by these terms. These terms are only used to distinguish one element, component, region, layer, doped type or section from another element, component, region, layer, doped type or section. Therefore, without departing from the teachings of the present disclosure, the first element, component, region, layer, doped type or section discussed below may a second element, component, region, layer or section.

Spatial relationship terms such as “under”, “beneath”, “lower”, “below”, “above”, and “upper” can be used herein to describe the relationship shown in the figure between one element or feature and another element or feature. It should be understood that in addition to the orientations shown in the figure, the spatial relationship terms further include different orientations of used and operated devices. For example, if a device in the accompanying drawings is turned over and described as being “beneath another element”, “below it”, or “under it”, the device or feature is oriented “on” the another element or feature. Therefore, the exemplary terms “beneath” and “under” may include two orientations of above and below. In addition, the device may further include other orientations (for example, a rotation by 90 degrees or other orientations), and the spatial description used herein is interpreted accordingly.

In this specification, the singular forms of “a”, “an” and “the/this” may also include plural forms, unless clearly indicated otherwise. It should also be understood that the terms such as “including/comprising” and “having” indicate the existence of the stated features, wholes, steps, operations, components, parts or combinations thereof. However, these terms do not exclude the possibility of the existence of one or more other features, wholes, steps, operations, components, parts or combinations thereof. In this case, in this specification, the term “and/or” includes any and all combinations of related listed items.

Embodiments of the present disclosure are described herein with reference to cross-sectional illustrations that are schematic diagrams of idealized embodiments (and intermediate structures) of the present disclosure, such that variations shown in the shapes can be contemplated due to, for example, manufacturing techniques and/or tolerances. Therefore, the embodiments of the present disclosure should not be limited to the specific shapes of the regions shown herein, but include shape deviations due to, for example, manufacturing technologies. The regions shown in the figure are schematic in nature their shapes are not intended to show the actual shapes of the regions of the device and limit the scope of the present disclosure.

As a commonly used semiconductor memory in electronic devices such as computers, a dynamic random access memory (DRAM) always includes a plurality of memory cells. The memory cells include: capacitors and transistors electrically connected to the capacitors. Capacitors are typically formed by first electrodes, second electrodes, and dielectric layers located between the first electrodes and the second electrodes. There are one or more dielectric layers.

It can be understood that in some embodiments, the first electrodes are columnar. The dielectric layer always needs to cover sidewalls of the first electrodes, that is, needs to be formed in the trenches of adjacent first electrodes. Considering the material and formation process of the dielectric layer, the step coverage of the dielectric layer is generally poor. As a result, the dielectric layer deposited on the sidewalls of the first electrodes is non-uniform. For example, a part of the dielectric layer at the bottoms of the first electrodes is relatively thin, while a part of the dielectric layer at the tops of the first electrodes is relatively thick, resulting in a relatively smaller capacitance value of the capacitor. In addition, the bottom of the dielectric layer is relatively thin, which is also likely to cause current leakages of the first electrodes.

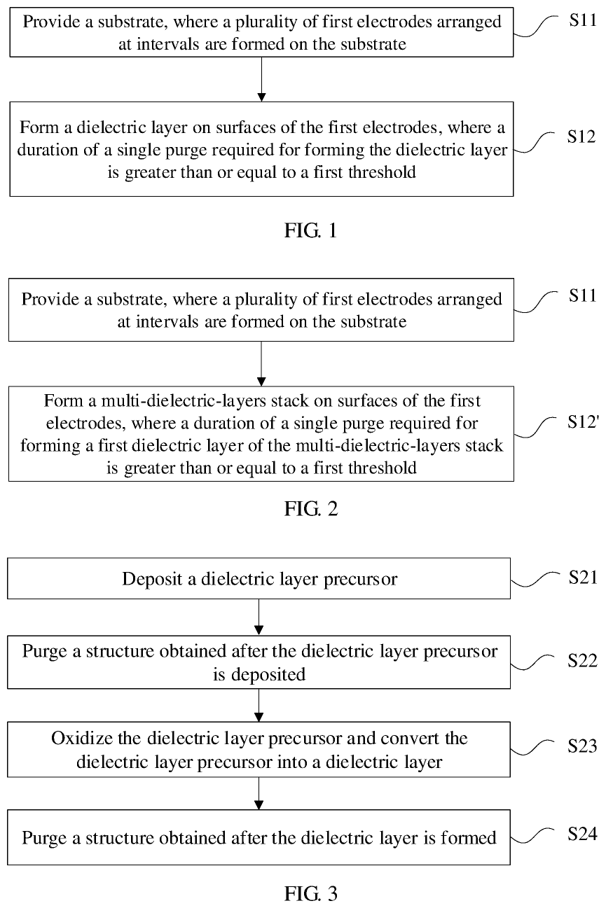

Based on this, with reference to FIG. 1, an embodiment of the present disclosure provides a manufacturing method of a semiconductor structure, including the following steps:

S11: Provide a substrate, where a plurality of first electrodes arranged at intervals are formed on the substrate;

S12: Form a dielectric layer on surfaces of the first electrodes, where a duration of a single purge required for forming the dielectric layer is greater than or equal to a first threshold. The value of the first threshold may be set according to an actual requirement. The first threshold is, for example, 90 s or 100 s.

In some embodiments, the first threshold is 90 s. Correspondingly, the duration of a single purge required for forming the dielectric layer ranges from 90 s to 120 s. For example, the duration of the single purge required for forming the dielectric layer is 90 s, 100 s, 110 s or 120 s.

With reference to FIG. 2, an embodiment of the present disclosure provides another manufacturing method of a semiconductor structure, including the following steps:

S11: Provide a substrate, where a plurality of first electrodes arranged at intervals are formed on the substrate.

S12′ : Form a multi-dielectric-layers stack on surfaces of the first electrodes, where a duration of a single purge required for forming a first dielectric layer of the multi-dielectric-layers stack is greater than or equal to the first threshold.

In this case, the value of the first threshold may be set according to an actual requirement. The first threshold is, for example, 90 s or 100 s.

In some embodiments, the first threshold is 90 s. Correspondingly, the duration of a single purge required for forming the first dielectric layer of the multi-dielectric-layers stack ranges from 90 s to 120 s. For example, the duration of the single purge required for forming the dielectric layer is 90 s, 100 s, 110 s or 120 s.

In addition, in some embodiments, a duration of a single purge required for forming another dielectric layer of the multi-dielectric-layers stack other than the first dielectric layer of the multi-dielectric-layers stack is less than that of the single purge required for forming the first dielectric layer of the multi-dielectric-layers stack. That is, after the first dielectric layer of the multi-dielectric-layers stack is formed, the duration of the single purge required in the process of forming the another dielectric layer of the multi-dielectric-layers stack may be properly reduced, to improve the product efficiency of the semiconductor structure.

In the embodiments of the present disclosure, the duration of the single purge required in the process of forming the dielectric layer or the duration of the single purge required for forming the first dielectric layer in the multi-dielectric-layers stack is limited. For example, the duration of the foregoing single purge is greater than or equal to the first threshold. In this way, a single purge with a longer duration can reduce or eliminate the residual water vapor that may occur during the formation of the dielectric layer, and improve the stability of the dielectric layer formation process, to ensure that a uniform dielectric layer is formed on the first electrodes, thereby improving the electrical performance of the capacitor, and avoiding current leakages and relatively small capacitance values due to the relatively small thickness of the partial dielectric layer.

It can be understood that the dielectric layer is always made of a high-k material. For example, the dielectric layer may be made of aluminum oxide (Al₂O₃), hafnium oxide (HfO₂), hafnium oxynitride (HfON), ZrO₂, tantalum oxide (Ta₂O₅), titanium oxide (TiO₂), or strontium titanium oxide material (SrTiO₃).

Based on this, in some embodiments, with reference to FIG. 3, steps of forming any one of the dielectric layers are as follows. In other words, in an example of forming the multi-dielectric-layers stack, the process of forming each of the dielectric layers can be implemented in the following steps:

S21: Deposit a dielectric layer precursor;

S22: Purge a structure obtained after the dielectric layer precursor is deposited;

S23: Oxidize the dielectric layer precursor and convert the dielectric layer precursor into the dielectric layer; and

S24: Purge a structure obtained after the dielectric layer is formed.

The single purge time mentioned in some of the foregoing embodiments may be the purge time in step S22 and the purge time in step S24.

It needs to be supplemented that in some embodiments, before step S21, the formation process of the dielectric layer further includes step S20.

S20: Pre-process a to-be-deposited surface of a dielectric layer precursor.

For example, ozone (O₃) is used to pre-process the to-be-deposited surface of the dielectric layer precursor. In this way, an O—H bond can be formed on the to-be-deposited surface of the dielectric layer precursor to enhance the adsorption capacity of the to-be-deposited surface to the dielectric layer precursor, thereby facilitating the conformal growth of the dielectric layer in the trench.

In addition, in the process of performing steps S22 and S24, limiting the duration of the single purge can effectively reduce or eliminate the residual water vapor caused by the O—H bond during the formation of the dielectric layer, and improve the stability of the dielectric layer formation process, thereby ensuring that the dielectric layer formed on the first electrodes is uniform.

It can be understood that the deposition quality of the dielectric layer precursor and the purge quality during the formation of the dielectric layer are likely to directly affect the dielectric constant and film-forming quality of the dielectric layer. Based on this, the embodiments of the present disclosure provide some specific and feasible implementations for the deposition temperature of the dielectric layer precursor, the type, flow rate, pressure and temperature of the purge gas during the formation of the dielectric layer, which, however, is not limited thereto.

In some embodiments, the dielectric layer precursor is deposited at a temperature less than or equal to a second threshold. The value of the second threshold may be set according to an actual requirement.

In some embodiments, the second threshold includes 260° C.

In some embodiments, the dielectric layer precursor is deposited at a temperature ranging from 230° C. to 250° C. For example, the dielectric layer precursor is deposited at a temperature of 230° C., 240° C. or 250° C.

In the embodiment of the present disclosure, by controlling the deposition temperature of the dielectric layer precursor to be less than the second threshold, a lower deposition temperature can be used for improving lattice structure of the dielectric layer precursor to effectively increase the dielectric constant of the dielectric layer. Therefore, under the same size condition, the amount of charge stored by the capacitor can be increased, to increase the capacitance value of the capacitor where the dielectric layer is located, thereby avoiding improving reading and writing efficiency and increasing energy consumption.

In some embodiments, a purge gas used in the process of forming the dielectric layer includes nitrogen or argon.

In some embodiments, in the process of forming the dielectric layer, a flow rate of the purge gas ranges from 800 sccm to 1600 sccm. For example, the flow rate of the purge gas is 800 sccm, 900 sccm, 1000 sccm, 1200 sccm, 1500 sccm or 1600 sccm.

In some embodiments, in the process of forming the dielectric layer, a pressure of the purge gas ranges from 0.2 torr to 2 torr. For example, the pressure of the purge gas is 0.2 torr, 0.5 torr, 0.8 torr, 1.0 torr, 1.5 torr or 2 torr.

In some embodiments, in the process of forming the dielectric layer, the temperature of the purge gas ranges from 200° C. to 350° C. For example, the temperature of the purge gas is 200° C., 220° C., 250° C., 280° C., 300° C., 320° C. or 350° C.

It is worth mentioning that in some embodiments, a capacitor includes a plurality of dielectric layers located between a first electrode and a second electrode. Two adjacent dielectric layers are made of different materials, and two adjacent dielectric layers include at least one wide-bandgap dielectric layer. In this way, the wide-bandgap dielectric layer can be used to further decrease a risk that current leakages occur to the capacitor.

In this case, the wide-bandgap dielectric layer is referred to as a dielectric layer of which a band gap is greater than 2.2 eV at a room temperature such as 25° C. or 20° C.

In addition, process conditions under which different dielectric layers are formed can be different and are set according to an actual requirement.

In some embodiments, a first dielectric layer of the multi-dielectric-layers stack formed on the surfaces of the first electrodes is the ZrO₂ dielectric layer.

In some embodiments, the wide-bandgap dielectric layer is an aluminum oxide (Al₂O₃) dielectric layer.

In some embodiments, a plurality of dielectric layers are a plurality of zirconium oxide (ZrO₂) dielectric layers and Al₂O₃ dielectric layers, the ZrO₂ dielectric layers and the Al₂O₃ dielectric layers are alternately arranged in a stacked manner.

In this case, the ZrO₂ dielectric layers and the Al₂O₃ dielectric layers both have relatively high dielectric constants. In addition, compared with the ZrO₂ dielectric layer, the Al₂O₃ dielectric layer has a wider band gap, thereby having a better anti-leakage capability.

In the embodiments of the present disclosure, two kinds of high-k materials with different dielectric constants and different band gaps are used to form a plurality of dielectric layers in the capacitors through discrete arrangement, which can ensure that the capacitors have optimal electrical performance.

Based on this, in some embodiments, step S12′ of forming the multi-dielectric-layers stack on surfaces of the first electrodes includes: forming a plurality of ZrO₂ dielectric layers and Al₂O₃ dielectric layers, the ZrO₂ dielectric layers and the Al₂O₃ dielectric layers are alternately arranged in a stacked manner on the surfaces of the first electrodes, where the first dielectric layer of the multi-dielectric-layers stack is one of the ZrO₂ dielectric layers.

In some embodiments, a dielectric layer precursor of each of the ZrO₂ dielectric layers includes a metal zirconium source. The metal zirconium source is, for example, a zirconium-containing gas.

In some embodiments, a dielectric layer precursor of each of the Al₂O₃ dielectric layers includes a metal aluminum source. The metal aluminum source is, for example, an aluminum-containing gas.

It can be understood that the dielectric layer precursor may be in a different form such as a gaseous, liquid or solid form in a different deposition environment (for example, under a different temperature and pressure). This is not limited in the embodiments of the present disclosure.

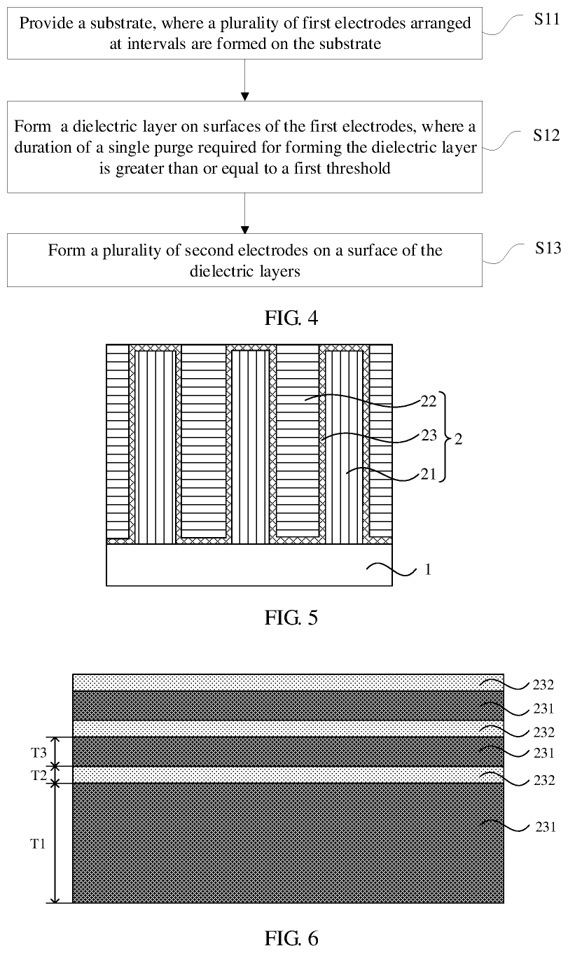

It needs to be supplemented that in some embodiments, with reference to FIG. 4, the manufacturing method of a semiconductor structure further includes step S13.

S13: Form a plurality of second electrodes on a surface of the dielectric layer.

In this way, one of the first electrodes, one of the second electrodes, and the dielectric layer located between the first electrode and the second electrode form a capacitor.

Based on the foregoing description, the manufacturing method of a semiconductor structure provided in the embodiments of the present disclosure effectively improves the manufacturing process of the capacitor in the semiconductor structure, to avoid defects such as current leakages and relatively small capacitance values due to the relatively small thickness of a partial dielectric layer, thereby ensuring the electrical performance of the semiconductor structure.

With reference to FIG. 5, some embodiments of the present disclosure further provide a semiconductor structure. The semiconductor structure includes: a substrate 1 and a plurality of capacitors 2 formed on the substrate 1. The capacitor 2 includes a first electrode 21, a second electrode 22 and at least one dielectric layer 23 located between the first electrode 21 and the second electrode 22. The capacitor 2 is formed by using the manufacturing method in the foregoing embodiments.

In an example, the substrate 1 includes but is not limited to a silicon substrate or a silicon-based substrate.

In some embodiments, the substrate 1 may be provided with circuit structures or electronic components connected to the capacitor 2. The circuit structures or electronic components may be set according to an actual requirement, and are not limited in the embodiments of the present disclosure.

With reference to FIG. 5, optionally, the first electrode 21 includes a columnar electrode. A second electrode accommodating hole is disposed between adjacent first electrodes 21. The second electrode 22 is corresponding located in the second electrode accommodating hole. In this way, adjacent first electrodes 21 can correspond to a same second electrode 22, to improve the distribution density of the capacitor 2 in the semiconductor structure.

It can be understood that the dielectric layer 23 is located between the first electrode 21 and the second electrode 22. In an example that the first electrode 21 is columnar, the dielectric layer 23 covers at least sidewalls (that is, the sidewalls of the first electrodes 21) of a second electrode accommodating hole between adjacent first electrodes 21. The second electrode 22 is disposed on the surface of a part of the dielectric layer 23 located in the second electrode accommodating hole.

The capacitor 2 in the embodiments of the present disclosure is obtained by using the manufacturing method in the foregoing embodiments. There are one or more dielectric layers 23 in the capacitor 2. The dielectric layer 23 is always made of a high-k material such as Al₂O₃, HfO₂, HfON, ZrO₂, Ta₂O₅, TiO₂ or SrTiO₃.

In some embodiments, with reference to FIG. 6, the at least one dielectric layer 23 in the capacitor 2 includes: a plurality of ZrO₂ dielectric layers 231 and Al₂O₃ dielectric layers 232, the ZrO₂ dielectric layers and the Al₂O₃ dielectric layers are alternately arranged in a stacked manner. A first dielectric layer close to the first electrode 21 is the ZrO₂ dielectric layer 231.

In this case, the ZrO₂ dielectric layers 231 and the Al₂O₃ dielectric layers 232 both have relatively high dielectric constants. In addition, compared with the ZrO₂ dielectric layer 231, the Al₂O₃ dielectric layer 232 has a wider band gap, thereby having a better anti-leakage capability.

In addition, the thicknesses of different dielectric layers 23 made of the same material in the capacitor 2 may be same or different.

In some embodiments, a thickness of the first dielectric layer 23 close to the first electrode 21 ranges from 3.5 nm to 5.5 nm.

For example, with reference to FIG. 6, the first dielectric layer close to the first electrode 21 is the ZrO₂ dielectric layer 231, and the thickness T1 of the ZrO₂ dielectric layer 231 is 3.5 nm, 4 nm, 4.5 nm, 5 nm or 5.5 nm.

In some embodiments, the thicknesses T3 of other ZrO₂ dielectric layers 231 than the first ZrO₂ dielectric layer 231 are the same. In some embodiments, the thicknesses T2 of different ZrO₂ dielectric layers 232 are the same.

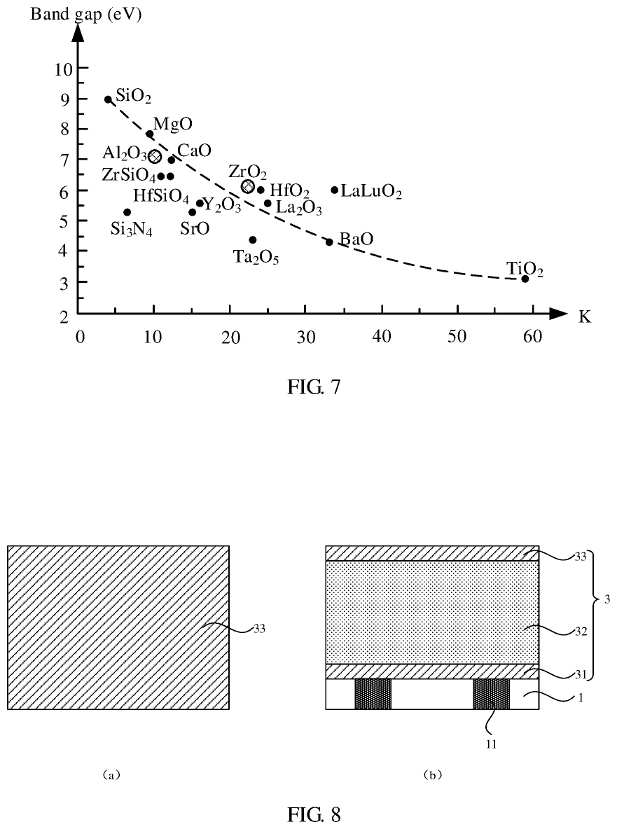

It can be understood that the dielectric layers 23 in the capacitor 2 may also be made of two high-k materials, with different dielectric constants and band gaps, arranged at intervals. With reference to FIG. 7, in a plurality of materials shown in FIG. 7, as the dielectric constant increases, a band gap of a corresponding material increasingly decreases. According to a design requirement of the dielectric layer 23 in the capacitor 2, a proper material may be selected from FIG. 7 to manufacture the dielectric layer 23.

Based on the foregoing description, in the embodiments of the present disclosure, two kinds of high-k materials with different dielectric constants and different band gaps are used to form the plurality of dielectric layers in the capacitors 2 through discrete arrangement, which can ensure that the capacitors 2 have optimal electrical performance

To more clearly describe the semiconductor structure and the manufacturing method thereof provided by the embodiments of the present disclosure, description is made below in detail by using the semiconductor structure used in the DRAM device as an example.

It can be understood that the semiconductor structure used in the DRAM device always includes a plurality of memory cells. The memory cells include: capacitors 2 and transistors electrically connected to the capacitors 2. The transistors include gates, source regions and drain regions. The gates of the transistors are used for electrical connection with word lines. The source regions of the transistors are used to form bit line contact regions to be electrically connected to bit lines by using bit line contact structures. The drain regions of the transistors are used to form memory node contact regions to be electrically connected to the capacitors 2 by using memory node contact structures. The capacitor 2 includes a first electrode 21, a second electrode 22 and at least one dielectric layer 23 located between the first electrode 21 and the second electrode 22. The capacitor 2 may be formed by using the foregoing manufacturing method in the following manufacturing process.

With reference to FIG. (a) and FIG (b) in FIG. 8, FIG. (a) is a top view corresponding to a manufactured structure, and FIG (b) is a cross-sectional view corresponding to a partial structure in the manufactured structure. A substrate 1 including prepared transistors and interconnection circuits (including memory node contact structures 11) is provided. The tops of the memory node contact structures 11 are exposed. Then, a dielectric-layer set 3 is formed on the substrate 1. The dielectric-layer set 3 is formed by at least two laminated dielectric layers made of different materials.

As shown in FIG (b) in FIG. 8, in an example, the dielectric-layer set 3 includes a first silicon nitride layer 31, a silicon oxide layer 32 and a second silicon nitride layer 33 laminated sequentially along a direction away from the substrate 1.

In another example, the dielectric-layer set 3 includes a boro-phospho-dilicate glass (BPSG) and a silicon nitride layer laminated sequentially along a direction away from the substrate 1.

In addition, the dielectric-layer set 3 is formed through a deposition process, which includes, but is not limited to a physical vapor deposition (PVD), a chemical vapor deposition (CVD), an atomic Layer deposition (ALD) or a furnace tube deposition process.

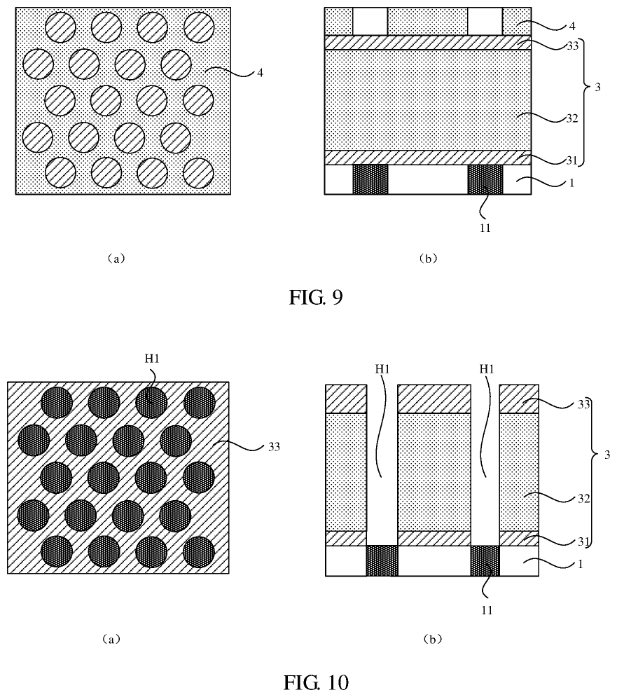

With reference to FIG. (a) and FIG (b) in FIG. 9, FIG. (a) is a top view corresponding to a manufactured structure, and FIG (b) is a cross-sectional view corresponding to a partial structure in the manufactured structure. A hard mask 4 is formed on the dielectric-layer set 3.

In some embodiments, the hard mask 4 may be formed by depositing a nitride, an oxide, a carbon or an organic anti-reflection (ARC) material.

It can be understood that the hard mask 4 and the corresponding contact dielectric layer in the dielectric-layer set 3 are made of different materials. In an example, with reference to FIG. 9, the hard mask 4 is in contact with the second silicon nitride layer 33. The hard mask 4 may be a silicon oxide layer.

In addition, the opening pattern in the hard mask 4 may be made through a photolithography process or self-aligned double patterning (SADP).

With reference to FIG (a) and FIG (b) in FIG. 10, FIG (a) is a top view corresponding to a manufactured structure, and FIG (b) is a cross-sectional view corresponding to a partial structure in the manufactured structure. The dielectric-layer set 3 is etched according to the opening pattern in the hard mask 4 to form the first electrode accommodating holes H1 corresponding to the memory node contact structures 11 one by one. The tops of the memory node contact structures 11 are exposed in the corresponding first electrode accommodating holes H1. Then, the hard mask 4 is removed.

The foregoing first electrode accommodating holes H1 may be made through the dry etching process or in another manner.

In some embodiments, the plurality of first electrode accommodating holes H1 are arranged in an array, and the first electrode accommodating holes H1 in adjacent rows are disposed in a staggered manner.

In some embodiments, a structure obtained after the hard mask 4 is removed, to ensure the quality of exposed surfaces of the memory node contact structures 11, thereby ensuring the electrical performance of the memory node contact structures 11.

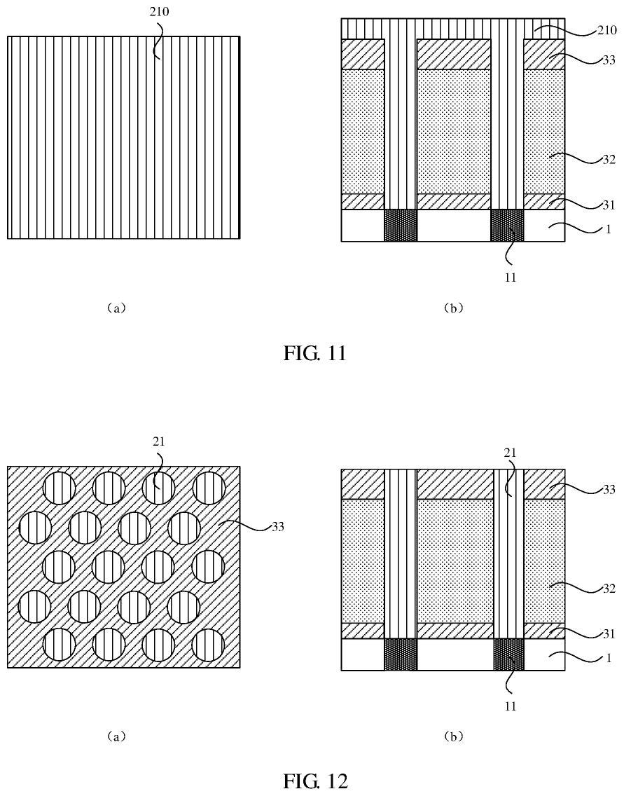

With reference to FIG (a) and FIG (b) in FIG. 11, FIG (a) is a top view corresponding to a manufactured structure, and FIG (b) is a cross-sectional view corresponding to a partial structure in the manufactured structure. A first electrode material layer 210 is deposited, partially fills the first electrode accommodating holes H1 and is in contact with corresponding memory node contact structures 11. The part of the first electrode material layer 210 filled in the first electrode accommodating holes H1 may be used to form the first electrodes 21 of the capacitors 2.

In some embodiments, the first electrode material layer 210 may be made of a conductive material such as titanium nitride (TIN), titanium (Ti) or tungsten (W).

It can be understood that the first electrode 21 may be connected to the memory node contact structure 11 directly or by using another conductive layer. For example, the first electrode 21 is connected to the memory node contact structure 11 by using a substrate layer. Correspondingly, in some examples, before the first electrode material layer 210 is deposited, a substrate material layer may be deposited first, and then the first electrode material layer 210 is deposited on the surface of the substrate material layer.

In some embodiments, the substrate material layer may be made of a TIN material.

With reference to FIG (a) and FIG (b) in FIG. 12, FIG (a) is a top view corresponding to a manufactured structure, and FIG (b) is a cross-sectional view corresponding to a partial structure in the manufactured structure. The part of the first electrode material layer 210 filled in the first electrode accommodating holes H1 is removed to form the first electrodes 21. For example, the part may be removed through a dry etching process and/or a chemical mechanical polishing (CMP) process.

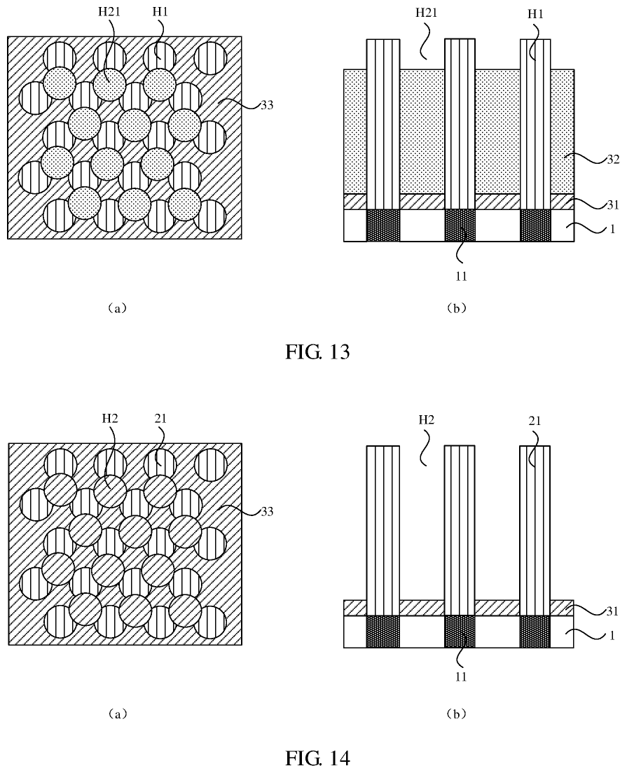

With reference to FIG (a) and FIG (b) in FIG. 13, FIG (a) is a top view corresponding to a manufactured structure, and FIG (b) is a cross-sectional view corresponding to a partial structure in the manufactured structure. The second silicon nitride layer 33 is patterned to form a plurality of basic second electrode accommodating holes H21.

In some embodiments, a plurality of adjacent first electrodes 21 may correspond to a same second electrode 22. In this way, the basic second electrode accommodating holes H21 can be properly set according to the arrangement positions of the first electrodes 21. For example, with reference to FIG (a) in FIG. 13, the basic second electrode accommodating hole H21 may be disposed at the center of the triangle formed by any three adjacent first electrodes 21.

With reference to FIG (a) and FIG (b) in FIG. 14, FIG (a) is a top view corresponding to a manufactured structure, and FIG (b) is a cross-sectional view corresponding to a partial structure in the manufactured structure. Based on the basic second electrode accommodating hole H21, the silicon oxide layer 32 is removed partially, to form the second electrode accommodating holes H2.

In some embodiments, the silicon oxide layer 32 may be removed partially through wet etching with, for example, a hydrofluoric acid (HF) solution.

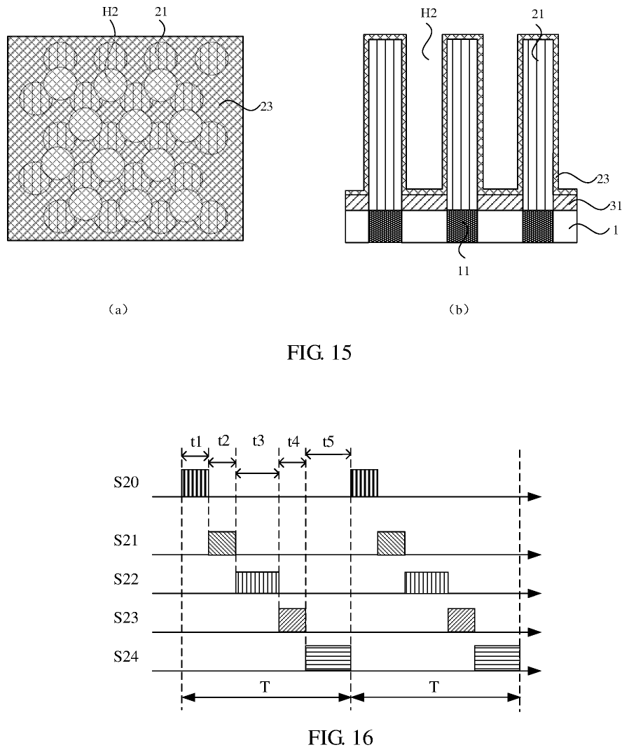

With reference to FIG (a) and FIG (b) in FIG. 15, FIG (a) is a top view corresponding to a manufactured structure, and FIG (b) is a cross-sectional view corresponding to a partial structure in the manufactured structure. At least one dielectric layer 23 is deposited. The dielectric layer 23 covers at least sidewalls (that is, the sidewalls of the first electrodes 21) of a second electrode accommodating hole H2 between adjacent first electrodes 21.

In addition, the first silicon nitride layer 31 may be a support layer of the dielectric layer 23.

With reference to FIG. 16, a formation cycle T of a deposition process on any dielectric layer 23 is shown in FIG. 16, and includes the following steps.

S20: Pre-process a to-be-deposited surface of a dielectric layer precursor in a first stage t1.

For example, O₃ is used to pre-process the to-be-deposited surface of the dielectric layer precursor. In this way, an O-H bond can be formed on the to-be-deposited surface of the dielectric layer precursor to enhance the adsorption capacity of the to-be-deposited surface to the dielectric layer precursor, thereby facilitating the conformal growth of the dielectric layer 23 in the second electrode accommodating holes H2.

S21: Deposit the dielectric layer precursor in a second stage t2.

In this case, different dielectric layers 23 correspond to different deposited dielectric layer precursors.

In some embodiments, the first dielectric layer 23 is the ZrO₂ dielectric layer, and its corresponding dielectric layer precursor includes a metal zirconium source. The metal zirconium source is, for example, a zirconium-containing gas.

In some embodiments, the second dielectric layer 23 is the Al₂O₃ dielectric layer and its dielectric layer precursor includes a metal aluminum source. The metal aluminum source is, for example, an aluminum-containing gas.

For example, optionally, the dielectric layer precursor is deposited at a temperature of 230° C., 240° C. or 250° C.

S22: Purge a structure obtained after the dielectric layer precursor is deposited in a third stage t3.

In some embodiments, the purge gas is, for example, nitrogen or argon.

In some embodiments, the purge duration is 90 s, 100 s, 110 s or 120 s.

In some embodiments, the flow rate of the purge gas is 800 sccm, 900 sccm, 1000 sccm, 1200 sccm, 1500 sccm or 1600 sccm.

In some embodiments, the pressure of the purge gas is 0.2 torr, 0.5 torr, 0.8 torr, 1.0 torr, 1.5 torr or 2 torr.

In some embodiments, the temperature of the purge gas is 200° C., 220° C., 250° C., 280° C., 300° C., 320° C. or 350° C.

S23: Oxidize the dielectric layer precursor and convert the dielectric layer precursor into the dielectric layer 23 in a fourth stage t4.

For example, oxygen (O₂) is introduced or other substances with oxidizing properties are provided, to oxidize the dielectric layer precursor, thereby obtaining the dielectric layer 23.

S24: Purge a structure obtained after the dielectric layer 23 is formed in a fifth stage t5.

In some embodiments, the purge gas is, for example, nitrogen or argon.

In some embodiments, the purge duration is 90 s, 100 s, 110 s or 120 s.

In some embodiments, the flow rate of the purge gas is 800 sccm, 900 sccm, 1000 sccm, 1200 sccm, 1500 sccm or 1600 sccm.

In some embodiments, the pressure of the purge gas is 0.2 torr, 0.5 torr, 0.8 torr, 1.0 torr, 1.5 torr or 2 torr.

In some embodiments, the temperature of the purge gas is 200° C., 220° C., 250° C., 280° C., 300° C., 320° C. or 350° C.

Based on the foregoing description, a uniform dielectric layer 23 can be formed, and it is ensured that the dielectric layer 23 has a relatively high dielectric constant and relatively stable anti-leakage performance

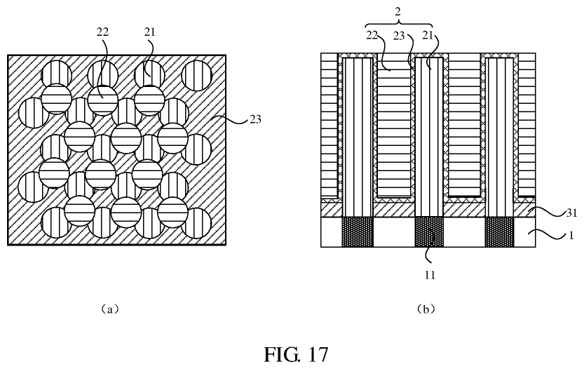

With reference to FIG (a) and FIG (b) in FIG. 17, FIG (a) is a top view corresponding to a manufactured structure, and FIG (b) is a cross-sectional view corresponding to a partial structure in the manufactured structure. The second electrodes 22 are formed on the outermost dielectric layer 23, and are located in corresponding second electrode accommodating holes H2. In this way, one of the first electrodes 21, one of the second electrodes 22, and the dielectric layer 23 located between the first electrode 21 and the second electrode 22 form a capacitor 2.

In some embodiments, the second electrodes 22 may be made of a conductive material such as TIN, Ti or W.

The technical characteristics of the foregoing examples can be employed in arbitrary combinations. To provide a concise description of these examples, all possible combinations of all technical characteristics of the embodiment may not be described; however, these combinations of technical characteristics should be construed as disclosed in the description as long as no contradiction occurs.

Only several embodiments of the present application are described in detail above, but they should not therefore be construed as limiting the scope of the present application. It should be noted that those of ordinary skill in the art can further make variations and improvements without departing from the conception of the present application. These variations and improvements all fall within the protection scope of the present application. Therefore, the protection scope of the present application should be subject to the protection scope defined by the claims.

1. A manufacturing method of a semiconductor structure, comprising:
providing a substrate, wherein a plurality of first electrodes arranged at intervals are formed on the substrate; and
forming a dielectric layer on surfaces of the first electrodes, wherein a duration of a single purge required for forming the dielectric layer is greater than or equal to a first threshold; or
forming a multi-dielectric-layers stack on the surfaces of the first electrodes, wherein a duration of a single purge required for forming a first dielectric layer of the multi-dielectric-layers stack is greater than or equal to the first threshold.

2. The manufacturing method of a semiconductor structure according to claim 1, wherein the forming a dielectric layer comprises:
depositing a dielectric layer precursor;
purging a structure obtained after the dielectric layer precursor is deposited;
oxidizing the dielectric layer precursor and converting the dielectric layer precursor into the dielectric layer; and
purging a structure obtained after the dielectric layer is formed.

3. The manufacturing method of a semiconductor structure according to claim 2, wherein the dielectric layer precursor is deposited at a temperature less than or equal to a second threshold.

4. The manufacturing method of a semiconductor structure according to claim 3, wherein the second threshold comprises 260° C.

5. The manufacturing method of a semiconductor structure according to claim 3, wherein the dielectric layer precursor is deposited at a temperature ranging from 230° C. to 250° C.

6. The manufacturing method of a semiconductor structure according to claim 1, wherein a purge gas used in the process of forming the dielectric layer comprises nitrogen or argon.

7. The manufacturing method of a semiconductor structure according to claim 6, wherein in the process of forming the dielectric layer, a flow rate of the purge gas ranges from 800 sccm to 1600 sccm; and a pressure of the purge gas ranges from 0.2 torr to 2 torr.

8. The manufacturing method of a semiconductor structure according to claim 6, wherein in the process of forming the dielectric layer, a temperature of the purge gas ranges from 200° C. to 350° C.

9. The manufacturing method of a semiconductor structure according to claim 1, wherein the first threshold comprises 90 s or 100 s.

10. The manufacturing method of a semiconductor structure according to claim 1, wherein
during the forming a dielectric layer on surfaces of the first electrodes, the duration of the single purge required for forming the dielectric layer ranges from 90 s to 120 s; and
during the forming a multi-dielectric-layers stack on the surfaces of the first electrodes, the duration of the single purge required for forming the first dielectric layer of the multi-dielectric-layers stack ranges from 90 s to 120 s.

11. The manufacturing method of a semiconductor structure according to claim 1, wherein during the forming a multi-dielectric-layers stack on the surfaces of the first electrodes, a duration of a single purge required for forming another dielectric layer of the multi-dielectric-layers stack other than the first dielectric layer of the multi-dielectric-layers stack is less than a duration of the single purge required for forming the first dielectric layer of the multi-dielectric-layers stack.

12. The manufacturing method of a semiconductor structure according to claim 11, wherein the multi-dielectric-layers stack comprises a plurality of zirconium oxide dielectric layers and aluminum oxide dielectric layers, the zirconium oxide dielectric layers and the aluminum oxide dielectric layers are alternately arranged in a stacked manner; and
the first dielectric layer of the multi-dielectric-layers stack is one of the zirconium oxide dielectric layers.

13. The manufacturing method of a semiconductor structure according to claim 12, wherein
a dielectric layer precursor of each of the zirconium oxide dielectric layers comprises a metal zirconium source; and
a dielectric layer precursor of each of the aluminum oxide dielectric layers comprises a metal aluminum source.

14. The manufacturing method of a semiconductor structure according to claim 1, wherein during the forming a multi-dielectric-layers stack on the surfaces of the first electrodes, two adjacent dielectric layers are made of different materials, and two adjacent dielectric layers comprise at least one wide-bandgap dielectric layer.

15. The manufacturing method of a semiconductor structure according to claim 14, wherein the wide-bandgap dielectric layer comprises an aluminum oxide dielectric layer.

16. The manufacturing method of a semiconductor structure according to claim 1, further comprising:
forming a plurality of second electrodes on a surface of the dielectric layer; wherein
one of the first electrodes, one of the second electrodes, and the dielectric layer located between the first electrode and the second electrode form a capacitor.

17. A semiconductor structure, comprising: a substrate and a plurality of capacitors formed on the substrate, wherein
each of the capacitors comprises a first electrode, a second electrode and at least one dielectric layer located between the first electrode and the second electrode; and
the capacitors are formed by using the manufacturing method of a semiconductor structure according to claim 1.

18. The semiconductor structure according to claim 17, wherein
the first electrode comprises a columnar electrode, and a second electrode accommodating hole is provided between adjacent first electrodes; and
the second electrode is located in the second electrode accommodating hole.

19. The semiconductor structure according to claim 17, wherein the at least one dielectric layer comprises a plurality of zirconium oxide dielectric layers and aluminum oxide dielectric layers, the zirconium oxide dielectric layers and the aluminum oxide dielectric layers are alternately arranged in a stacked manner; and
a first dielectric layer close to the first electrode is the zirconium oxide dielectric layer.

20. The semiconductor structure according to claim 19, wherein a thickness of the first dielectric layer close to the first electrode ranges from 3.5 nm to 5.5 nm.
